(19) United States
(12) Patent Application Publication
(10) Pub. No.: US 2024/0224436 A1
(43) Pub. Date: Jul. 4, 2024

(54) INTERPOSER BOARD AND CIRCUIT BOARD INCLUDING THE SAME

(71) Applicant: SAMSUNG ELECTRO-MECHANICS CO., LTD., Suwon-si (KR)

(72) Inventors: Young Kuk Ko, Suwon-si (KR); Sanghoon Kim, Suwon-si (KR); Jiho Yoon, Suwon-si (KR); Gyumook Kim, Suwon-si (KR); Taehun Kim, Suwon-si (KR); Sukchang Hong, Suwon-si (KR); Seongil Jeon, Suwon-si (KR); Woo-Jeong Choi, Suwon-si (KR)

(73) Assignee: SAMSUNG ELECTRO-MECHANICS CO., LTD., Suwon-si (KR)

(21) Appl. No.: 18/235,062

(22) Filed: Aug. 17, 2023

(30) Foreign Application Priority Data
Dec. 30, 2022 (KR) 10-2022-0190558
Jul. 19, 2023 (KR) 10-2023-0094162

(51) Int. Cl. H05K 3/46; H05K 1/02; H05K 3/10; H05K 3/34

(52) U.S. Cl. CPC H05K 3/465; H05K 1/0284; H05K 3/103; H05K 3/3457; H05K 3/4697; H05K 2201/10378

(57) ABSTRACT

A circuit board according to an embodiment includes: a first substrate; and an interposer board that is located on the first substrate, and includes a first insulating layer having a first surface and a second surface facing each other, a first wiring layer buried in the first surface of the first insulating layer, a second insulating layer located on the second surface of the first insulating layer, a cavity disposed in a part of the first insulating layer, and a first trench connected to the cavity; an electronic component disposed between the first substrate and the interposer board, and at least partially disposed in the cavity; and a molding layer located between the first substrate and the interposer board.

### CROSS-REFERENCE TO RELATED APPLICATION

This application claims priority to and the benefit of Korean Patent Application No. 10-2022-0190558 filed in the Korean Intellectual Property Office on Dec. 30, 2022, and Korean Patent Application No. 10-2023-0094162 filed in the Korean Intellectual Property Office on Jul. 19, 2023, the entire contents of each of which are incorporated herein by reference.

### TECHNICAL FIELD

This disclosure relates to an interposer board and a circuit board including the same.

### BACKGROUND

Printed circuit boards are boards having circuit patterns made of conductive materials such as copper on insulating materials, and as electronic devices in the IT field, including mobile phones, have been miniaturized. A method of forming cavities in a printed circuit board and placing electronic components such as ICs, active components, or passive components in the cavities has been proposed.

After the electronic components are placed in the cavities of the printed circuit board, molding layers are formed in the cavities to seal them such that it is possible to prevent foreign matter from getting inside, thereby preventing electric damage to the electronic components.

At this time, the molding layers may be nonuniformly formed in the cavities, and some positions may not be filled with the molding material, resulting in defects such as voids.

If defects such as voids occur inside the molding layers for sealing the electronic components, air, moisture, and so on may remain in the voids, and the electronic components placed in the cavities where air or moisture exists may be damaged.

The above information disclosed in this Background section is only for enhancement of understanding of the background of the described technology, and therefore it may contain information that does not form the prior art that is already known in this country to a person of ordinary skill in the art.

### SUMMARY

The present disclosure has been made in an effort to provide an interposer board, and a circuit board including the same, having advantages of being capable of reducing occurrence of defects such as voids in a molding layer located around cavities.

However, problems that embodiments are to solve are not limited to the above-described object, and can be variously expanded within the scope of technical spirits included in the embodiments.

An embodiment of the present disclosure provides an interposer board including a first insulating layer having a first surface and a second surface facing each other; a first wiring layer buried in the first surface of the first insulating layer; a second insulating layer disposed on the second surface of the first insulating layer; a cavity disposed in a part of the first surface of the first insulating layer; and a first trench connected to the cavity along a first direction and disposed in the part of the first surface of the first insulating layer.

A depth of the cavity may be substantially equal to a depth of the first trench.

The interposer board may further include a first solder resist layer located under the first surface of the first insulating layer. The cavity and the first trench may be disposed in the part of the first insulating layer and the first solder resist layer.

The depth of the cavity and the depth of the first trench may be substantially equal to a sum of a thickness of the first wiring layer and a thickness of the first solder resist layer.

The cavity may include an additional cavity extending from the cavity, disposed in the first insulating layer, and having a width narrower than a width of the cavity, and the first trench may include an additional trench extending from the trench, disposed in the first insulating layer, and having a width narrower than a width of the first trench.

The cavity may be substantially equal to a sum of a thickness of the first wiring layer, a thickness of the first solder resist layer, and a depth of the additional cavity, and the depth of the first trench may be substantially equal to a sum of the thickness of the first wiring layer, the thickness of the first solder resist layer, and a depth of the additional trench.

A depth of the cavity may be different from a depth of the first trench.

The interposer board may further include a first solder resist layer located under the first insulating layer. The cavity may be disposed in the part of the first insulating layer and the first solder resist layer, and the first trench may be disposed in the first solder resist layer.

The depth of the cavity may be substantially equal to a sum of a thickness of the first wiring layer and a thickness of the first solder resist layer, and the depth of the first trench may be substantially equal to the thickness of the first solder resist layer.

The cavity each may include an additional cavity extending from the cavity, disposed in the first insulating layer, and having a width narrower than a width of the cavity.

The depth of the cavity may be substantially equal to a sum of the thickness of the first wiring layer, a thickness of the first solder resist layer, and a depth of the additional cavity, and the depth of the first trench may be substantially equal to a sum of the thickness of the first wiring layer and the thickness of the first solder resist layer.

The first trench may extend along the first direction, and the first trench may include a plurality of trenches located along a second direction different from the first direction.

The interposer board may further include a plurality of protrusions disposed in the cavity and extending from a bottom of the cavity.

The interposer board may further include a second trench connected to the cavity and disposed on a side of the cavity opposite to another side of the cavity where the first trench is disposed.

An embodiment of the present disclosure provides a circuit board including: a first substrate; and an interposer board that is located on the first substrate, and includes a first insulating layer having a first surface and a second surface facing each other, a first wiring layer buried in the first surface of the first insulating layer, a second insulating layer located on the second surface of the first insulating layer, a cavity disposed in a part of the first insulating layer, and a first trench connected to the cavity; an electronic component disposed between the first substrate and the interposer board, and at least partially disposed in the cavity; and a molding layer located between the first substrate and the interposer board.

According to the embodiments, it is possible to provide an interposer board, and a circuit board including the same, capable of reducing occurrence of defects such as voids in a molding layer located around cavities.

However, the effects of the embodiments are not limited to the above-described effects, and it is apparent that they can be variously expanded without departing from the spirit and scope of the present disclosure.

### BRIEF DESCRIPTION OF THE DRAWINGS

FIG. 1 is a cross-sectional view illustrating a part of a circuit board according to an embodiment.

FIG. 2 is a layout drawing of an interposer board according to the embodiment.

FIG. 3 is a schematic cross-sectional view taken along a line A-A′ of FIG. 2.

FIG. 4 is a schematic cross-sectional view taken along a line B-B′ of FIG. 2.

FIG. 5 is a schematic cross-sectional view taken along a line C-C′ of FIG. 2.

FIG. 6 and FIG. 7 are plan views illustrating a method of manufacturing a circuit board according to an embodiment.

FIG. 8 is a plan view illustrating a part of an interposer board of a circuit board according to another embodiment.

FIG. 9 is a cross-sectional view taken along a line A-A′ of FIG. 8.

FIG. 10 is a plan view illustrating a part of an interposer board of a circuit board according to another embodiment.

FIG. 11 is a cross-sectional view taken along a line A-A′ of FIG. 10.

FIG. 12 is a cross-sectional view taken along a line B-B′ of FIG. 10.

FIG. 13 is a plan view illustrating a part of an interposer board of a circuit board according to another embodiment.

FIG. 14 is a cross-sectional view taken along a line A-A′ of FIG. 13.

FIG. 15 is a cross-sectional view taken along a line B-B′ of FIG. 13.

FIG. 16 is a plan view illustrating a part of an interposer board of a circuit board according to another embodiment.

FIG. 17 is a cross-sectional view taken along a line A-A′ of FIG. 16.

FIG. 18 is a cross-sectional view taken along a line B-B′ of FIG. 16.

FIG. 19 is a plan view illustrating a part of an interposer board of a circuit board according to another embodiment.

FIG. 20 is a cross-sectional view taken along a line A-A′ of FIG. 19.

FIG. 21 is a cross-sectional view taken along a line B-B′ of FIG. 19.

### DETAILED DESCRIPTION

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

Further, the accompanying drawings are provided for helping to easily understand embodiments disclosed in the present specification, and the technical spirit disclosed in the present specification is not limited by the accompanying drawings, and it will be appreciated that the present disclosure includes all of the modifications, equivalent matters, and substitutes included in the spirit and the technical scope of the present disclosure.

In addition, the size and thickness of each configuration shown in the drawings are arbitrarily shown for understanding and ease of description, but the present disclosure is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Further, throughout the specification, when it is referred to as “connected”, this does not only mean that two or more constituent elements are directly connected, but may mean that two or more constituent elements are indirectly connected through another constituent element, are physically connected, electrically connected, or are integrated even though two or more constituent elements are referred as different names depending on a location and a function.

Hereinafter, various embodiments and modifications will be described in detail with reference to the drawings.

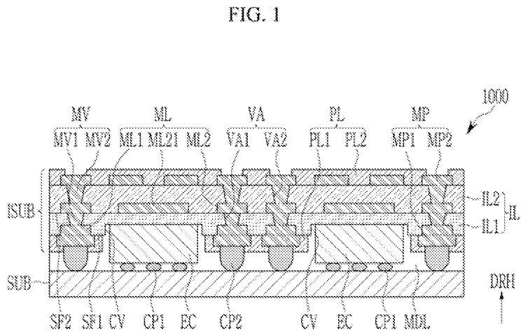

A circuit board 1000 according to an embodiment will be described with reference to FIG. 1. FIG. 1 is a cross-sectional view illustrating a part of a circuit board according to an embodiment.

Referring to FIG. 1, the circuit board 1000 according to the present embodiment includes a first substrate SUB, an interposer board ISUB located on the first substrate SUB, a plurality of electronic components EC located between the first substrate SUB and the interposer board ISUB, a plurality of first connection parts CP1 that electrically connects the plurality of electronic components EC and the first substrate SUB, a plurality of second connection parts CP2 that electrically connects the first substrate SUB and the interposer board ISUB, and a molding layer MDL located between the first substrate SUB and the interposer board ISUB.

The interposer board ISUB may include a plurality of insulating layers IL stacked, a plurality of wiring layers ML buried in the plurality of insulating layers IL and a plurality of via layers MV located in a plurality of vias VA of the plurality of insulating layers IL, a plurality of pad layers MP, solder resist layers PL, and cavities CV formed in some parts of the plurality of insulating layers IL.

The plurality of insulating layers IL may include a first insulating layer IL1, and a second insulating layer IL2 located on the first insulating layer IL1.

The plurality of wiring layers ML may include a plurality of first connection wiring layers ML1 buried in the first insulating layer IL1, and the plurality of wiring layers ML21 and a plurality of second connection wiring layers ML2 buried in the second insulating layer IL2.

The plurality of via layers MV may include first via layers MV1 located in first vias VA1 formed in the first insulating layer IL1, and second via layers MV2 located in second vias VA2 formed in the second insulating layer IL2.

The plurality of pad layers MP may include a plurality of first pad layers MP1 located under the first insulating layer IL1, and a plurality of second pad layers MP2 located on the second insulating layer IL2.

The first connection wiring layers ML1 and the second connection wiring layers ML2 may be connected through the first via layers MV1, and the second connection wiring layers ML2 and the second pad layers MP2 may be connected through the second via layers MV2, and the first pad layers MP1 may be connected to the first connection wiring layers ML1.

The first insulating layer IL1 may have a first surface SF1 and a second surface SF2 facing each other, the first connection wiring layers ML1 may be buried in the first surface SF1 of the first insulating layer IL1, and the second insulating layer IL2 may be disposed on the second surface SF2 of the first insulating layer IL1.

The solder resist layers PL may include a first solder resist layer PL1 that is located under the first surface SF1 of the first insulating layer IL1, exposes parts of the plurality of first pad layers MP1, and has parts of the cavities CV formed therein, and a second solder resist layer PL2 that is located on the second insulating layer IL2 and exposes parts of the plurality of second pad layers MP2.

The cavities CV may be formed in the first solder resist layer PL1 and a part of the first surface SF1 of the first insulating layer IL1 along the height direction DRH. The depth of the cavities CV formed in the parts of the first insulating layer IL1 may be substantially equal to the thickness of the first connection wiring layers ML1 buried in the first insulating layer IL1. In one example, the configuration in which one element being substantially equal to another element may indicate that the one element being equal to the another element or may indicate that there is a slight difference between the one element and the another element, recognizable by one of ordinary skill in the art, due to, for example, process errors or positional deviations occurring during the manufacturing process, or errors during measurement.

Therefore, the depth of the cavities CV may be equal to the sum of the thickness of the first solder resist layer PL1 and the thickness of the first connection wiring layers ML1.

As described above, the interposer board ISUB may include at least one cavity CV, and at least one electronic component EC may be placed such that at least part of that is located in the cavity CV of the interposer board ISUB. However, the embodiment is not limited thereto.

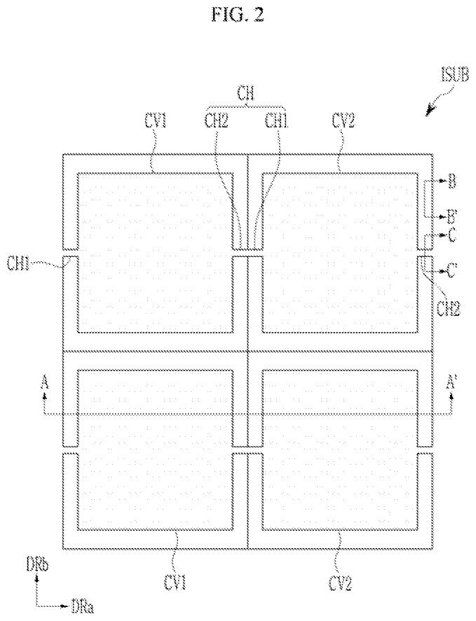

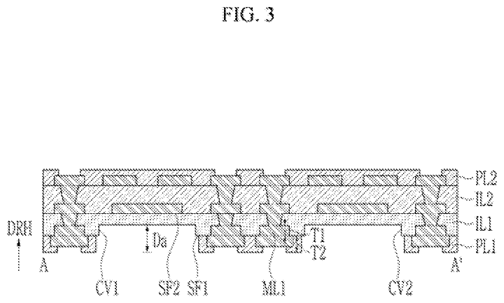

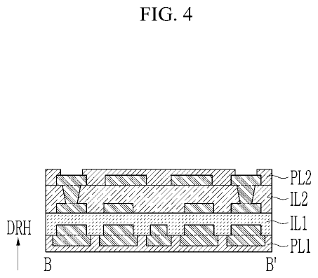

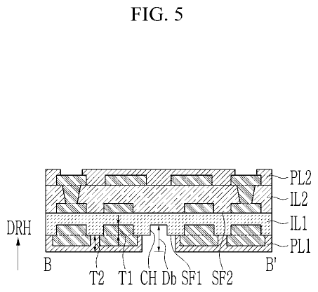

Now, the interposer board ISUB of the circuit board 1000 according to the embodiment will be described with reference to FIG. 1 to FIG. 5. FIG. 2 is a layout drawing of an interposer board according to an embodiment, FIG. 3 is a schematic cross-sectional view taken along a line A-A′ of FIG. 2, and FIG. 4 is a schematic cross-sectional view taken along a line B-B′ of FIG. 2, and FIG. 5 is a schematic cross-sectional view taken along a line C-C′ of FIG. 2.

Referring to FIG. 2, the interposer board ISUB of the circuit board 1000 according to the embodiment may include the plurality of cavities CV in which the plurality of electronic components EC are disposed, and a plurality of trenches CH that are located between the plurality of cavities and each of which connects two adjacent cavities CV.

The plurality of cavities CV of the interposer board ISUB may be located in sets of a plurality of cavities along a first direction DRa and a second direction DRb, and the plurality of trenches CH may have a planar shape extending along the first direction DRa, and be arranged adjacent to others in a line along the first direction DRa.

On both sides of each cavity CV in the first direction DRa, a first trench CH1 and a second trench CH2 connected to the cavity CV may be located.

With respect to a first cavity CV1 and a second cavity CV2 adjacent to each other in the first direction DRa, a second trench CH2 connected to the first cavity CV1 and a first trench CH1 connected to the second cavity CV2 may be connected to each other, such that the first cavity CV1 and the second cavity CV2 can be connected through the second trench CH2 and the first trench CH1 located between the first cavity CV1 and the second cavity CV2.

On both sides of each cavity CV in the first direction DRa, a first trench CH1 and a second trench CH2 connected to the cavity CV may be arranged substantially in a line.

Referring to FIG. 3 to FIG. 5, the cavities CV may be formed in the first solder resist layer PL1 and a part of the first surface SF1 of the first insulating layer IL1 along the height direction DRH. The depth Da of the cavities CV may be substantially equal to the sum of the thickness T1 of the first connection wiring layers ML1 buried in the first insulating layer IL1 and the thickness T2 of the first solder resist layer PL1. Similarly, the plurality of trenches CH may be formed in the first solder resist layer PL1 and a part of the first surface SF1 of the first insulating layer IL1 along the height direction DRH, and the depth Db of the trenches CH may be substantially equal to the sum of the thickness T1 of the first connection wiring layer ML1 buried in the first insulating layer IL1 and the thickness T2 of the first solder resist layer PL1.

The depth Da of the cavities CV may be substantially equal to the depth Db of the trenches CH.

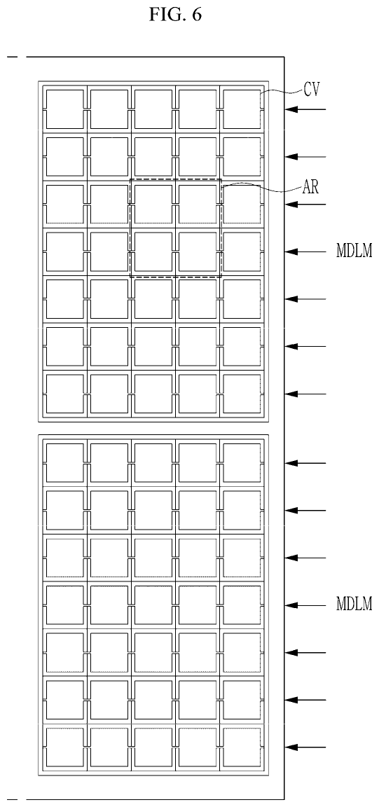

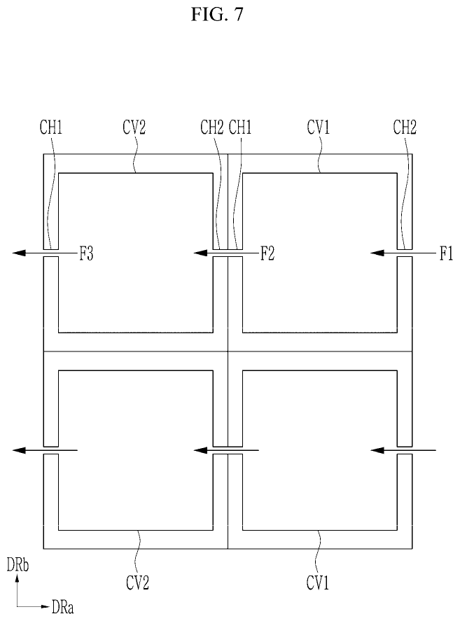

A method of manufacturing the circuit board 1000 according to an embodiment will be described in brief with reference to FIG. 6 and FIG. 7 together with FIG. 1 to FIG. 5. FIG. 6 and FIG. 7 are plan views illustrating the method of manufacturing the circuit board according to the embodiment. FIG. 7 is an enlarged view of a partial area AR of FIG. 6.

In the method of manufacturing the circuit board 1000 according to the present embodiment, the interposer board ISUB may be formed to have the plurality of cavities CV, and the plurality of electronic components EC may be placed on the first substrate SUB with the plurality of first connection parts CP1 interposed therebetween, and the first substrate SUB and the interposer board ISUB may be electrically connected through the plurality of second connection parts CP2 such that the plurality of electronic components EC are located in the plurality of cavities CV of the interposer board ISUB, and molding layers MDL may be formed by supplying a molding material MDLM as shown by arrows in FIG. 6, and injecting the molding material MDLM between the first substrate SUB and the interposer board ISUB, using osmotic pressure or the like, and curing the injected molding material MDLM.

At this time, since the gap between the first substrate SUB and the interposer board ISUB widens in the areas of the interposer board ISUB where the plurality of cavities CV has been formed, and the plurality of electronic components EC is located in the plurality of wide cavities CV, it may be difficult for the molding material to be uniformly filled in the plurality of cavities CV. In such a case where the molding material is not uniformly filled, voids containing no molding material may be formed.

The interposer board ISUB of the circuit board 1000 according to the embodiment may include not only the plurality of cavities CV in which the plurality of electronic components EC is disposed, but also the plurality of trenches CH that is connected to the plurality of cavities CV, and the trenches CH may connect two adjacent cavities CV during manufacturing process. Referring to FIG. 7 together with FIG. 2 to FIG. 5, of a first cavity CV1 and a second cavity CV2 adjacent to each other in the first direction DRa, the first cavity CV1 has trenches CH1 and CH2 connected to both sides thereof, the second trench CH2 of which may be located on the side to which the molding material MDLM is supplied, and serve as an inflow path for the molding material MDLM, such that the molding material MDLM can be additionally introduced into the first cavity CV1 through the second trench CH2 (reference symbol F1). The molding material MDLM additionally introduced through the second trench CH2 (reference symbol F1) as described above can diffuse inside the first cavity CV1, and flow from the first cavity CV1 into the second cavity CV2 through the first trench CH1 connected to the first cavity CV1 and another second trench CH2 connected to the second cavity CV2 (reference symbol F2), and further flow through another first trench CH1 connected to the second cavity CV2 (reference symbol F3).

As described above, the molding material MDLM to be supplied to the plurality of cavities CV may be additionally supplied to each cavity CV through the trenches CH connected to the cavity CV, as well as by the osmotic phenomenon, whereby it is possible to assist the molding material MDLM in being uniformly filled in the plurality of cavities CV. Therefore, it is possible to reduce formation of voids containing no molding material in each cavity CV.

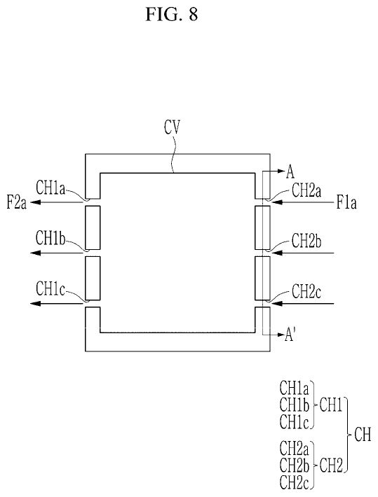

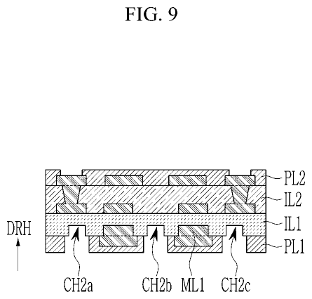

Now, an interposer board of a circuit board according to another embodiment will be described with reference to FIG. 8 and FIG. 9. FIG. 8 is a plan view illustrating a part of an interposer board of a circuit board according to another embodiment, and FIG. 9 is a cross-sectional view taken along a line A-A′ of FIG. 8.

Referring to FIG. 8 and FIG. 9, similarly to the interposer boards ISUB of the circuit boards according to the above-described embodiments, the interposer board ISUB of the circuit board according to the present embodiment may include at least one trench CH connected to one cavity CV, and the trench CH connected to the cavity CV may include a first trench CH1 and a second trench CH2 located on both sides of the cavity CV in the first direction DRa and connected to the cavity CV.

However, unlike the interposer boards ISUB of the circuit boards according to the above-described embodiments, the first trench CH1 and the second trench CH2 located on both sides of the cavity CV and connected to the cavity CV of the interposer board ISUB of the circuit board according to the present embodiment may include a plurality of trenches CH1a, CH1b, and CH1c and a plurality of trenches CH2a, CH2b, and CH2c arranged in the second direction DRb, respectively.

The plurality of trenches CH1a, CH1b, and CH1c of the first trench CH1 connected to the cavity CV may be located to be substantially in line with the plurality of trenches CH2a, CH2b, and CH2c of the second trench CH2 connected to the cavity CV along the first direction DRa, respectively.

The molding material MDLM can be additionally introduced into the cavity CV through the plurality of trenches CH2a, CH2b, and CH2c of the second trench CH2 as described above (reference symbol Fla), and diffuse in the cavity CV evenly. Then, through the plurality of trenches CH1a, CH1b, and CH1c of the first trench CH1 connected to the cavity CV, the molding material MDLM can further flow into an adjacent cavity CV (reference symbol F2a). Therefore, it is possible to assist the molding material MDLM in being uniformly filled in the cavity CV, and it is possible to reduce formation of voids containing no molding material in each cavity CV.

All of the numerous features of the interposer board according to the embodiment described above with reference to FIG. 1 to FIG. 7 can be applied to the interposer board according to the present embodiment.

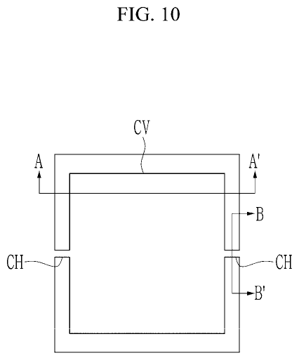

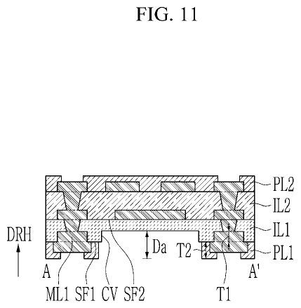

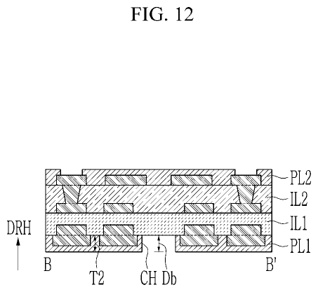

Now, an interposer board of a circuit board according to another embodiment will be described with reference to FIG. 10 to FIG. 12. FIG. 10 is a plan view illustrating a part of an interposer board of a circuit board according to another embodiment, FIG. 11 is a cross-sectional view taken along a line A-A′ of FIG. 10, and FIG. 12 is a cross-sectional view taken along a line B-B′ of FIG. 10.

Referring to FIG. 10 to FIG. 12, similarly to the interposer boards ISUB of the circuit boards according to the embodiments described above, the interposer board ISUB of the circuit board according to the present embodiment may include at least one trench CH connected to the cavity CV.

Referring to FIG. 11 and FIG. 12, the cavity CV may be formed in the first solder resist layer PL1 and a part of the first surface SF1 of the first insulating layer IL1 along the height direction DRH. The depth Da of the cavity CV may be substantially equal to the sum of the thickness T1 of the first connection wiring layers ML1 buried in the first insulating layer IL1 and the thickness T2 of the first solder resist layer PL1. On the other hand, the trench CH may be formed in the first solder resist layer PL1 along the height direction DRH, and the depth Db of the trench CH may be substantially equal to the thickness T2 of the first solder resist layer PL1. The depth Da of the cavity CV may be larger than the depth Db of the trench CH.

All of the numerous features of the interposer boards according to the embodiments described above with reference to FIG. 1 to FIG. 9 can be applied to the interposer board according to the present embodiment.

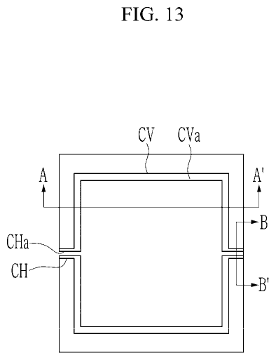

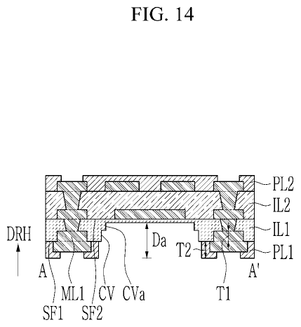

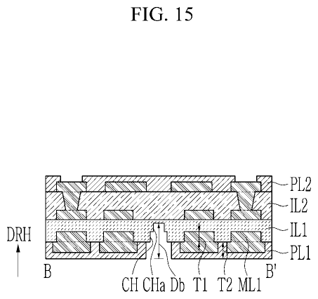

Now, an interposer board of a circuit board according to another embodiment will be described with reference to FIG. 13 to FIG. 15. FIG. 13 is a plan view illustrating a part of an interposer board of a circuit board according to another embodiment, FIG. 14 is a cross-sectional view taken along a line A-A′ of FIG. 13, and FIG. 15 is a cross-sectional view taken along a line B-B′ of FIG. 13.

Referring to FIG. 13 to FIG. 15, similarly to the interposer boards ISUB of the circuit boards according to the embodiments described above, the interposer board ISUB of the circuit board according to the present embodiment may include at least one trench CH connected to the cavity CV.

Referring to FIG. 14 and FIG. 15, the cavity CV may be formed in the first solder resist layer PL1 and a part of the first surface SF1 of the first insulating layer IL1 along the height direction DRH, and the cavity CV may further include additional cavity CVa that extends from the cavity CV, is formed in the first insulating layer IL1, and is narrower than the cavity CV.

Similarly, the trench CH may be formed in the first solder resist layer PL1 and a part of the first surface SF1 of the first insulating layer IL1 along the height direction DRH, and may further include an additional trench CHa that is formed in the first insulating layer IL1 and is narrower than the trench CH.

Therefore, the depth Da of the cavity CV may be substantially equal to the sum of the thickness T1 of the first connection wiring layers ML1 buried in the first insulating layer IL1, the thickness T2 of the first solder resist layer PL1, and the depth of the additional cavity CVa.

The depth Db of the trench CH may be substantially equal to the sum of the thickness T1 of the first connection wiring layer ML1 buried in the first insulating layer IL1, the thickness T2 of the first solder resist layer PL1, and the depth of the additional trench CHa.

The depth Da of the cavity CV may be substantially equal to the depth Db of the trench CH.

All of the numerous features of the interposer boards according to the embodiments described above with reference to FIG. 1 to FIG. 12 can be applied to the interposer board according to the present embodiment.

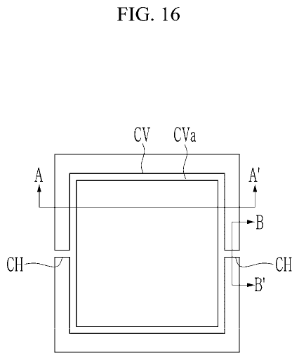

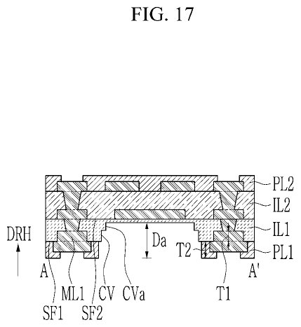

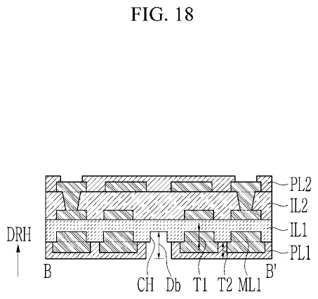

Now, an interposer board of a circuit board according to another embodiment will be described with reference to FIG. 16 to FIG. 18. FIG. 16 is a plan view illustrating a part of an interposer board of a circuit board according to another embodiment, FIG. 17 is a cross-sectional view taken along a line A-A′ of FIG. 16, and FIG. 18 is a cross-sectional view taken along a line B-B′ of FIG. 16.

Referring to FIG. 16 to FIG. 18, similarly to the interposer boards ISUB of the circuit boards according to the embodiments described above, the interposer board ISUB of the circuit board according to the present embodiment may include at least one trench CH connected to the cavity CV.

Referring to FIG. 17, the cavity CV may be formed in the first solder resist layer PL1 and a part of the first surface SF1 of the first insulating layer IL1 along the height direction DRH, and the cavity CV may further include additional cavity CVa that is formed in the first insulating layer IL1 and is narrower than the cavity CV.

Therefore, the depth Da of the cavity CV may be substantially equal to the sum of the thickness T1 of the first connection wiring layers ML1 buried in the first insulating layer IL1, the thickness T2 of the first solder resist layer PL1, and the depth of the additional cavity CVa.

Referring to FIG. 18, the trench CH may be formed in the first solder resist layer PL1 and a part of the first surface SF1 of the first insulating layer IL1 along the height direction DRH.

The depth Db of the trench CH may be substantially equal to the sum of the thickness T1 of the first connection wiring layer ML1 buried in the first insulating layer IL1 and the thickness T2 of the first solder resist layer PL1.

The depth Da of the cavity CV may be larger than the depth Db of the trench CH.

All of the numerous features of the interposer boards according to the embodiments described above with reference to FIG. 1 to FIG. 15 can be applied to the interposer board according to the present embodiment.

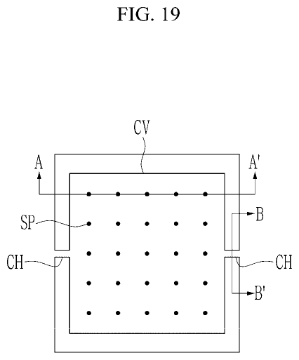

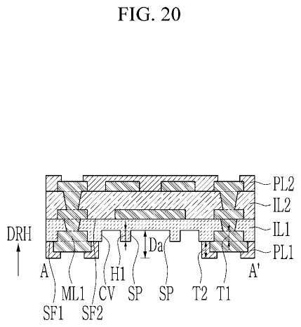

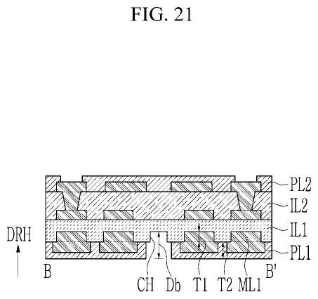

An interposer board of a circuit board according to another embodiment will be described with reference to FIG. 19 to FIG. 21. FIG. 19 is a plan view illustrating a part of an interposer board of a circuit board according to another embodiment, FIG. 20 is a cross-sectional view taken along a line A-A′ of FIG. 19, and FIG. 21 is a cross-sectional view taken along a line B-B′ of FIG. 19.

Referring to FIG. 19 and FIG. 21, similarly to the interposer boards ISUB of the circuit boards according to the above-described embodiments, the interposer board ISUB of the circuit board according to the present embodiment may include at least one trench CH connected to the cavity CV.

However, unlike the circuit boards according to the above-described embodiments, the interposer board ISUB of the circuit board according to the present embodiment may further include a plurality of protrusions SP extending from the first insulating layer IL1 in the cavity CV.

Referring to FIG. 20, the thickness H1 of the plurality of protrusions SP may be substantially equal to the first thickness T1 of the first connection wiring layer ML1 which is buried in the first insulating layer IL1.

The plurality of protrusions SP may serve as spacers. Since the plurality of protrusions SP formed in the cavity CV are further included, when an electronic component is placed in the cavity CV, spaces can be generated around the electronic component, and heat generated by the electronic component and so on can diffuse through these spaces.

Referring to FIG. 21, the cavity CV may be formed in the first solder resist layer PL1 and a part of the first surface SF1 of the first insulating layer IL1 along the height direction DRH.

Therefore, the depth Da of the cavity CV may be substantially equal to the sum of the thickness T1 of the first connection wiring layers ML1 buried in the first insulating layer IL1 and the thickness T2 of the first solder resist layer PL1.

The depth Db of the trench CH may be substantially equal to the sum of the thickness T1 of the first connection wiring layer ML1 buried in the first insulating layer IL1 and the thickness T2 of the first solder resist layer PL1.

The depth Da of the cavity CV may be substantially equal to the depth Db of the trench CH.

All of the numerous features of the interposer boards according to the embodiments described above with reference to FIG. 1 to FIG. 18 can be applied to the interposer board according to the present embodiment.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An interposer board comprising:
a first insulating layer having a first surface and a second surface facing each other;
a first wiring layer buried in the first surface of the first insulating layer;
a second insulating layer disposed on the second surface of the first insulating layer;
a cavity disposed in a part of the first surface of the first insulating layer; and
a first trench connected to the cavity along a first direction and disposed in the part of the first surface of the first insulating layer.

2. The interposer board of claim 1, wherein:
a depth of the cavity is substantially equal to a depth of the first trench.

3. The interposer board of claim 2, further comprising:
a first solder resist layer located under the first surface of the first insulating layer,
wherein the cavity and the first trench are disposed in the part of the first insulating layer and the first solder resist layer.

4. The interposer board of claim 3, wherein:
the depth of the cavity and the depth of the first trench are substantially equal to a sum of a thickness of the first wiring layer and a thickness of the first solder resist layer.

5. The interposer board of claim 3, wherein:
the cavity includes an additional cavity extending from the cavity, disposed in the first insulating layer, and having a width narrower than a width of the cavity, and
the first trench includes an additional trench extending from the trench, disposed in the first insulating layer, and having a width narrower than a width of the first trench.

6. The interposer board of claim 5, wherein:
the depth of the cavity is substantially equal to a sum of a thickness of the first wiring layer, a thickness of the first solder resist layer, and a depth of the additional cavity, and
the depth of the first trench is substantially equal to a sum of the thickness of the first wiring layer, the thickness of the first solder resist layer, and a depth of the additional trench.

7. The interposer board of claim 1, wherein:
a depth of the cavity is different from a depth of the first trench.

8. The interposer board of claim 7, further comprising:
a first solder resist layer located under the first insulating layer,
wherein the cavity is disposed in the part of the first insulating layer and the first solder resist layer, and
the first trench is disposed in the first solder resist layer.

9. The interposer board of claim 8, wherein:
the depth of the cavity is substantially equal to a sum of a thickness of the first wiring layer and a thickness of the first solder resist layer, and
the depth of the first trench is substantially equal to the thickness of the first solder resist layer.

10. The interposer board of claim 7, wherein:
the cavity includes an additional cavity extending from the cavity, disposed in the first insulating layer, and having a width narrower than a width of the cavity.

11. The interposer board of claim 10, wherein:
the depth of the cavity is substantially equal to a sum of the thickness of the first wiring layer, a thickness of the first solder resist layer, and a depth of the additional cavity, and
the depth of the first trench is substantially equal to a sum of the thickness of the first wiring layer and the thickness of the first solder resist layer.

12. The interposer board of claim 1, wherein:
the first trench extends along the first direction, and
the first trench includes a plurality of trenches located along a second direction different from the first direction.

13. The interposer board of claim 1, further comprising:
a plurality of protrusions disposed in the cavity and extending from a bottom of the cavity.

14. The interposer board of claim 1, further comprising:
a second trench connected to the cavity and disposed on a side of the cavity opposite to another side of the cavity where the first trench is disposed.

15. A circuit board comprising:
a first substrate; and
an interposer board that is located on the first substrate, and includes a first insulating layer having a first surface and a second surface facing each other, a first wiring layer buried in the first surface of the first insulating layer, a second insulating layer located on the second surface of the first insulating layer, a cavity disposed in a part of the first insulating layer, and a first trench connected to the cavity;
an electronic component disposed between the first substrate and the interposer board, and at least partially disposed in the cavity; and
a molding layer located between the first substrate and the interposer board.

16. The circuit board of claim 15, wherein:
the interposer board further includes a first solder resist layer located under the first surface of the first insulating layer, and
the cavity and the first trench are disposed in the part of the first insulating layer and the first solder resist layer.

17. The circuit board of claim 15, wherein:
the first trench extends along a first direction, and
the first trench includes a plurality of trenches located along a second direction different from the first direction.

18. The circuit board of claim 15, wherein:
the interposer board further includes a first solder resist layer located under the first surface of the first insulating layer,
the cavity is disposed in the part of the first insulating layer and the first solder resist layer, and
the first trench is disposed in the first solder resist layer.

19. The circuit board of claim 15, wherein:
the cavity includes an additional cavity extending from the cavity, disposed in the first insulating layer, and having a width narrower than a width of the cavity, and
the first trench includes an additional trench extended from the trench, disposed in the first insulating layer, and having a width narrower than a width of the first trench.

20. The circuit board of claim 15, further comprising:
a plurality of protrusions disposed in the cavity and extending from a bottom of the cavity.
